(19) United States
(12) Patent Application Publication
(10) Pub. No.: US 2004/0201388 A1
(43) Pub. Date: Oct. 14, 2004

(54) Support for an electronic probe and related methods

(76) Inventor: Andrew Harvey Barr, Roseville, CA (US)

Correspondence Address: HEWLETT-PACKARD COMPANY, Intellectual Property Administration, P.O. Box 272400, Fort Collins, CO, 80527-2400, US

(21) Appl. No.: 10/410,532

(22) Filed: Apr. 8, 2003

(51) Int. Cl. G01R 31/02

(52) U.S. Cl. 324/754

(57) ABSTRACT

A stand for supporting a probe includes a support mountable to the electronic device being probed, and a clamp coupled to the support and operable to hold the probe. With the stand, a technician no longer has to hold a probe to maintain contact between the probe and a circuit node being probed. Thus, a test/diagnosis of an electronic device that requires the probe to remain in contact with the node for a long period of time is more likely to be accurate; a technician may use his/her hands to operate an oscilloscope during the test/diagnosis; and a lone technician may probe a device with two or more probes. In addition, the stand may be adjustable to support the probe in a desired position and/or the clamp may be removable and may be positionable relative to the support to hold the probe in a desired position.

### BACKGROUND

Many electronic devices, such as computers and stereos, include a circuit board that contains the device's circuitry for operating the device. For example, a circuit board may include a microprocessor for executing instructions and a memory for storing data and application software that includes instructions to be executed by the microprocessor. When such devices malfunction or when the design or manufacture of such devices is not complete, a technician typically tests/diagnosis the device by probing nodes of the device's circuit board with a probe coupled to a measuring device, such as an oscilloscope. The nodes may be, e.g., pads on the circuit board or leads of components.

To probe a circuit and/or component of a circuit board, the technician typically contacts a conductive lead of the probe to a node of the circuit and/or component and then holds the probe with his/her hand to maintain contact. Thus, probing a circuit and/or component of the circuit board typically requires the technician to use at least one of his/her hands to support the probe.

Unfortunately, holding the probe with a hand while testing/diagnosing an electronic device is often clumsy and awkward. Frequently, testing/diagnosing requires a technician to probe a circuit and/or component for long periods of time, and thus, often requires the technician to hold the probe for a long period of time to complete the test/diagnosis. Holding the probe for a long period frequently tires the technician's hand, wrist and/or arm, which can cause loss of contact between the probe and the circuit and/or component. If proper contact is not maintained, the signal sensed by the probe may be degraded or lost, and the test/diagnosis may be inaccurate. In addition, testing/diagnosing an electronic device frequently requires a technician to operate the controls of the measuring device (oscilloscope) while probing the circuit node. This often causes the technician to lose his/her concentration on maintaining contact between the probe and the circuit node. Furthermore, testing/diagnosing an electronic device may require contacting two or more probes to respective nodes of the circuit board, and thus, may require two or more technicians to hold the probes, which may be difficult in a tight space and is often an inefficient use of resources.

### SUMMARY

In one aspect of the invention, a stand for supporting a probe includes a support mountable to the electronic device that is being probed, and a clamp coupled to the support and operable to retain a probe to the stand. With the stand, a technician no longer has to hold a probe to maintain contact between the probe and the circuit node. In addition, the support of the stand may be adjustable to support the probe in a desired position and/or the clamp may be removable and may be positionable relative to the support to retain the probe in a desired position.

### BRIEF DESCRIPTION OF THE FIGURES

FIG. 1 is a view of a probe and a probe stand according to an embodiment of the invention.

FIG. 2A is a perspective view of the clamp of FIG. 1 according to an embodiment of the invention.

FIG. 2B is a perspective view of an alternative clamp that may be used in the stand in FIG. 1 according to another embodiment of the invention.

FIG. 3A is a view of a support that may be incorporated by the stand of FIG. 1 according to an embodiment of the invention.

FIG. 3B is a view of an alternative support that may be incorporated in the stand of FIG. 1 according to another embodiment of the invention.

FIG. 4 is a view of the stand of FIG. 1 incorporating a ground-lead support according to another embodiment of the invention.

### DETAILED DESCRIPTION

The following discussion is presented to enable one skilled in the art to make and use the invention. Various modifications to the disclosed embodiments will be readily apparent to those skilled in the art, and the generic principles herein may be applied to other embodiments and applications without departing from the spirit and scope of the present invention as defined by the appended claims. Thus, the present invention is not intended to be limited to the embodiments shown, but is to be accorded the widest scope consistent with the principles and features disclosed herein.

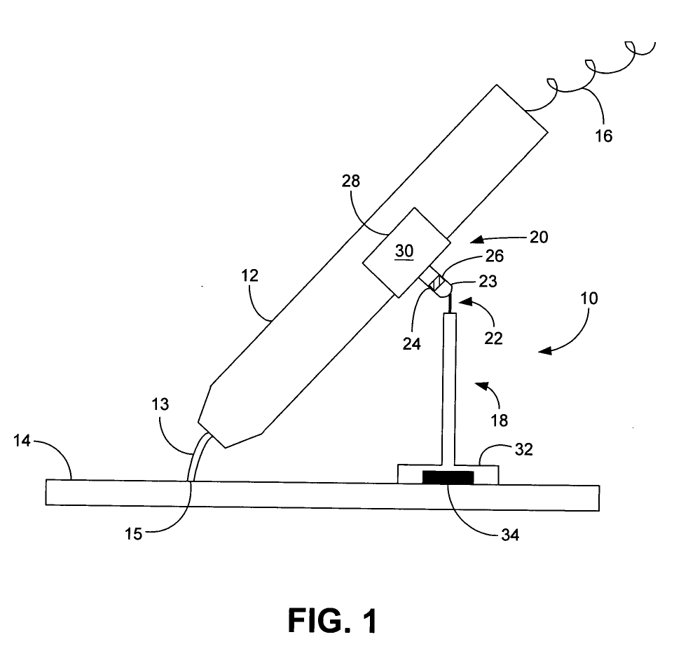

FIG. 1 is a view of a probe stand 10 according to an embodiment of the invention. The stand 10 supports a probe 12 that is probing a node 15 of a circuit board 14 of an electronic device such as a computer. The probe 12 includes a conductive tip 13 that contacts the node 15 to sense an electrical signal generated in a circuit (not shown) in the board 14. The probe 12 is also coupled to a second electronic device (not shown), such as an oscilloscope, via the cable 16 to provide the second electronic device the sensed signal. The stand 10 includes a support 18 that is mountable to the circuit board 14 of the electronic device, and a clamp 20 to retain the probe 12 to the stand 10. By supporting the probe 12 with the stand 10 as the probe 12 senses an electrical signal, the technician does not have to hold the probe 12 with his/her hand. Thus, the technician may use his/her hand to operate the oscilloscope (not shown) coupled to the probe 12.

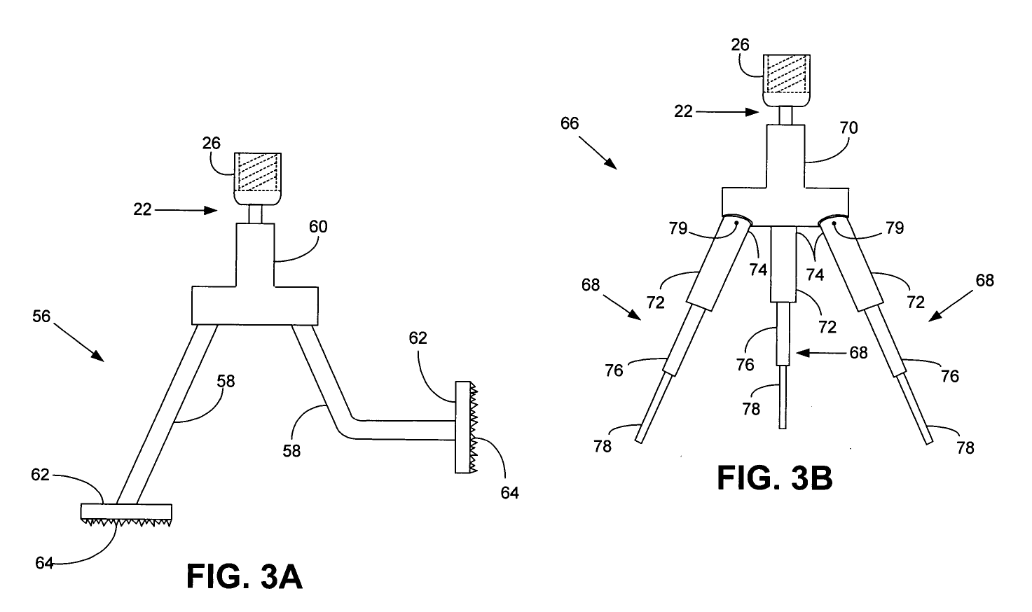

The stand 10 may support the probe 12 at any desired position relative to the circuit board 14 to facilitate access to the node 15 or to another node to be probed, and provides substantially stable support for the probe 12. To support the probe 12 in a desired position, the support 18 may be bendable (as discussed in conjunction with FIG. 3A) and/or extendable (as discussed in conjunction with FIG. 3B). Furthermore, the clamp 20 may be positionable relative to the support 18. For example, the clamp 20 may be positioned to retain the probe 12 at a substantially 450 angle to avoid a component (not shown) that may be mounted close to the node 15. Alternatively, the clamp 20 may be positioned to retain the probe 12 substantially perpendicular to the support 18. Thus, the orientation of the probe 12 to the circuit board 14 may be changed to allow access to a node that would otherwise be difficult to probe.

Still referring to FIG. 1, in one embodiment, the support 18 includes a conventional universal joint 22 that allows positioning of the clamp 20 relative to the support 18 and that may be locked to maintain the clamp at the desired position. The universal joint 22 may include a ball (not shown) that slides within a socket 23 when the clamp 20 is positioned relative to the support 18. To lock the clamp 20 at a desired position, a set screw (not shown) may be threaded through a portion of the socket 23 and forced against the ball to frictionally secure the ball in the socket 23. In other embodiments, the support 18 may include another type of conventional joint or hinge.

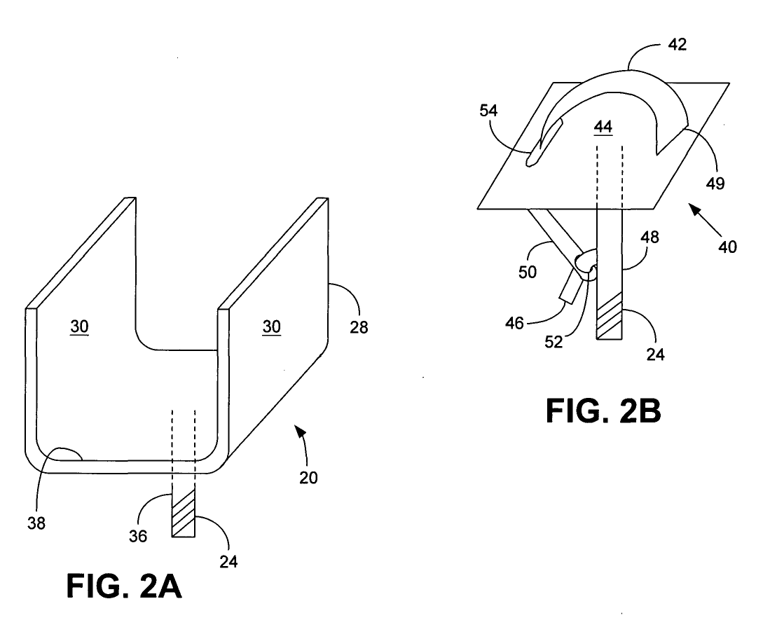

In addition, the clamp 20 may be releasably coupled to the support 18 to allow a technician to swap the clamp 20 with a different clamp (discussed in greater detail in conjunction with FIG. 2B) or to substitute the support 18 with a different support (discussed in greater detail in conjunction with FIGS. 3A and 3B). A technician may want to substitute the clamp 20 for a different clamp that can retain a probe having a different body size and/or shape than the probe 12, and may want to swap the support 18 for a different support that allows one to mount the stand 10 to the circuit board 14 differently. In one embodiment, the clamp 20 may include a thread 24 that receives a thread 26 of the support 18 to releasably couple the clamp 20 to the support 18.

Still referring to FIG. 1, the clamp 20 may retain the probe 12 using any desired technique. In one embodiment (discussed in greater detail in conjunction with FIG. 2A), the clamp 20 includes a “U”-shaped body 28 that receives the probe 12 between two sides 30 (only one shown) that steady the probe 12. To retain the probe 12 when the clamp 20 is angled relative to the support 18, the “U”-shaped body 28 may include a conventional, friction enhancing material (not shown) that contacts the probe 12, or the sides 30 may pinch the probe 12. In another embodiment of the stand 10, such as the one discussed in FIG. 2B, the clamp 20 may retain the probe 12 with a strap that is adjustable to allow the clamp 20 to retain a probe having a different size and/or shape than the probe 12.

Still referring to FIG. 1, the support 18 may be mounted to the circuit board 14 using any desired technique. In one embodiment, the support 18 includes a foot 32 that includes a magnet 34 for mounting the stand 10 to magnetic material in the electronic device such as a metal component of the circuit board 14 or a metal housing (not shown). To minimize corruption of the electronic signal sensed by the probe 12 and other possible damage to the electronic device, the foot 32 may also include a magnetic shield (not shown). In addition, the foot 32 may include a pin (not shown) that may be inserted into a hole in the circuit board 14 to mount the stand 10 in a region of a circuit board 14 that may be adversely affected by the presence of a magnetic field. In another embodiment of the stand 10, such as the embodiments discussed in greater detail in conjunction with FIGS. 3A and 3B, the foot 32 may include adhesive to help prevent the support 18 from slipping on the circuit board 14, and/or the stand 10 may include two or more legs to mount the stand 10 without securing the stand to the circuit board 14.

Other embodiments of the support 18 are contemplated. For example the support 18 may include a foot having a vise that may be clamped around an edge of a circuit board or housing of the electronic device.

FIG. 2A is a perspective view of the clamp 20 of FIG. 1 according to an embodiment of the invention. The clamp 20 includes a post 36 to couple the clamp 20 to the support 18 (FIG. 1), and a “U”-shaped body 28 to retain the probe 12. The post 36 includes an external thread 24 to receive the thread 26 (FIG. 1), and thus, allows a technician to remove the clamp 20 from the support 18. The “U”-shaped body 28 includes a bottom 38 and two sides 30, and may pinch the probe 12 to retain the probe 12. The “U”-shaped body 28 may be made from any conventional material that can elastically deform, such as plastics and/or metals, when subjected to a force. When inserted between the sides 30, the probe 12 forces the sides 30 away from each other. This deforms a portion of the elastic material—typically the material located at the transition of the side 30 to the bottom 38—of the “U”-shaped body 28. Because the material deformation is elastic, each side 30 generates a force toward the other side that pinches the probe 12.

FIG. 2B is a perspective view of a clamp 40 that may be used in place of the clamp 20 incorporated in the stand 10 in FIG. 1, according to another embodiment of the invention. The clamp 40 includes a strap 42 and mounting surface 44 to retain the probe 12 to the stand 10. The clamp 40 also includes a cleat 46 extending from the post 48 to releasably attach the strap 42 to the post 48. The strap 42 includes a first end 49 fastened to the mounting surface 44, and a second end 50 having a hole 52 for receiving the cleat 46. The strap 42 may be made of any conventional elastic material such as rubber to retain one or more probes 12 having a variety of sizes and shapes. To retain the probe 12 a technician inserts the strap 42 through a slot 54 in the mounting surface 44 and inserts the cleat 46 through the hole 52 in the second end 50.

In other embodiments, the strap 42 may be made of a material that is less elastic than rubber to more securely retain a probe to the stand 10. In addition, the second end 50 of the strap 42 may include two or more holes 52 to allow adjustment of the strap 42 such that probes having a variety of shapes and sizes may be retained by the clamp 40.

Still referring to FIGS. 2A and 2B, other embodiments of the clamps 20 and 40 are contemplated. For example, the strap 42 may include a buckle or Velcro® to allow adjustment of the strap's length. Furthermore, any conventional clamp suitable for holding the probe 12 may be used with the stand 10.

FIG. 3A is a view of a support 56 that may be used in place of the support 18 in the stand 10 of FIG. 1 according to an embodiment of the invention. The support 56 includes conventional material that plastically deforms when bent, i.e., retains its new shape. Thus, a technician may bend the support 56 to support the probe 12 (FIG. 1) in a desired position. Bending the support may be desirable to avoid contact with a component (not shown) and/or circuit (not shown) of the circuit board 14 (FIG. 1) that a technician would be unable to avoid otherwise. For example, a technician may bend the support 56 over a component (not shown) and/or circuit (not shown) of the circuit board 14 that is adjacent the probed node 15 (FIG. 1). Or the technician may bend the support 56 to mount the stand 10 to another circuit board (not shown) or housing (not shown) of the electronic device (not shown) that is perpendicular to the probed circuit board 14 (FIG. 1).

In one embodiment, the support includes two legs 58, each made of conventional material that plastically deforms when bent and each including a foot 62 having an adhesive 64 to mount the support 56 to an electronic device to be probed. The adhesive 64 can be any desired adhesive. For example, the adhesive 64 can be a reusable adhesive and/or reusable putty that retains the support 56 to any desired location on an electronic device and that remains with the foot 62 when the foot 62 is removed from the electronic device. Alternatively, a permanent/nonreuseable adhesive or magnets may be used. In addition, the support 56 includes a body 60 having a universal joint 22 (as discussed in conjunction with FIG. 1) to couple the clamp 20 (FIG. 1) or clamp 40 (FIG. 2B) to the support 56, and an internal thread 26 (FIG. 1) to receive the thread 24 (FIGS. 1-2B) to releasably couple the clamp 20 or the clamp 40 to the support 56.

FIG. 3B is a view of another support 66 that may be used in place of the support 18 in the stand 10 of FIG. 1 according to another embodiment of the invention. The support 66 includes one or more telescoping legs 68 that may be extended away from and retracted toward a body 70 to adjust the position of the clamp 20 (FIG. 1) or 40 (FIG. 2B) relative to the circuit board 14 (FIG. 1). Thus, a technician may locate the probe in a desired position to facilitate probing of a circuit node 15 (FIG. 1) of an electronic device (not shown) and/or provide substantially stable support for the probe 12.

In one embodiment, the support 66 includes three legs 68 that are pivotally coupled to a body 70 and that may be extended away from the body 70. The body 70 includes universal joint 22 (as discussed in conjunction with FIG. 1) to pivotally couple the clamp 20 (FIG. 1) or clamp 40 (FIG. 2B) to the support 66, and an internal thread 26 to releasably couple the clamp to the support 66 by receiving the thread 24 (FIGS. 1-2B) of the clamp. Each leg 68 includes a first section 72 having a proximate end 74 pivotally coupled to the body 70, a second section 76, and a third section 78. To allow each leg 68 to extend away from and retract toward the body 70, the third section 78 may slide within the second section 76, and the second section 76 may slide within the first section 72. Thus, each leg 68 may have a minimal length substantially defined by the length of the first section 72 when the third and second sections 78 and 76, respectively, are nested inside the respective second and first sections 76 and 72, respectively. And each leg 68 may have a maximum length substantially defined by the sum of the lengths of the first, second and third sections 72, 76 and 78, respectively.

A technician may also adjust the position of the clamp 20 or 40 relative to the circuit board 14 by pivoting a leg 68 relative to the body 70. In one embodiment, the proximate end 74 may be pivotally coupled to the body 70 using any desired technique, such as a pin 79 inserted into the body 70 proximate to end 74. The pin 79 allows the body 70 and proximate end 74 to pivot relative to each other but does not allow the proximate end 74 to be moved away from the body 70. Alternatively, the leg 72 may be attached to the body 70 with a universal-type joint. The support may also include a lock (not shown) to retain the first sections 72 at desired angles relative to the body 70.

Other embodiments of the support 66 are contemplated. For example, each leg 68 may include more or fewer than three telescoping sections.

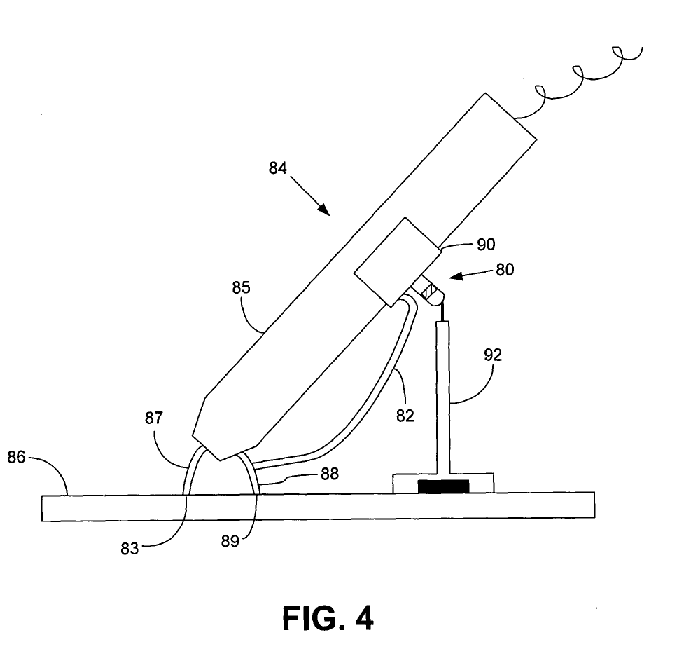

FIG. 4 is a perspective view of a stand 80 that incorporates a ground-lead holder 82 according to another embodiment of the invention. Technicians often use an active probe 84, i.e., a probe that includes circuitry (not shown) within the body 85 to probe a high-frequency node 83 on a circuit board 86. The active probe 84 includes a primary tip 87 that receives the high-frequency signal from the node 83 and includes a ground lead 88 that contacts a ground node 89. By including the ground lead 88 close to the tip 87, the length of the high-frequency signal path from the tip 87 to the lead 88 is minimized, thus minimizing degradation of the probed signal due to noise pick up or path impedence.

To maintain contact between the ground lead 88 and the node 89, the stand 80 includes the ground-lead holder 82. The stand 80 is similar to the stand 10 (FIG. 1) except that the stand 80 includes the ground-lead holder 82, which may be coupled to the clamp 90 or the support 92 as desired and may be releasably coupled to the ground lead 88 as desired. For example, the ground-lead holder 82 may be coupled to the clamp 90 with conventional adhesive and may be releasably coupled to the ground lead 88 with a lockable jaw (not shown) that may be opened to insert a portion of the ground lead 88 into the jaw and then may be closed to retain the ground lead 88. The ground-lead holder 82 may also be made of conventional, plastically deformable material to allow a technician to move the ground lead holder 82 as desired to support a ground lead of a variety of different active probes 84.

What is claimed is:

1. A stand for supporting a signal probe, comprising:
a support mountable to an electronic device that is to be probed; and
a clamp coupled to the support and operable to hold the signal probe.

2. The stand of claim 1 wherein the support is adjustable to support the probe at a desired position.

3. The stand of claim 1 wherein the clamp is positionable relative to the support to hold the probe in a desired position.

4. The stand of claim 1 wherein the support is releasably mountable to the electronic device.

5. The stand of claim 1 wherein the clamp is releasably coupled to the support.

6. The stand of claim 1, further comprising a universal joint that couples the support to the clamp.

7. The stand of claim 1 wherein the support includes a magnet operable to mount the support to the electronic device.

8. The stand of claim 1 wherein the support includes an adhesive operable to mount the support to the electronic device.

9. The stand of claim 1 wherein the support includes a telescoping leg operable to adjust a position of the clamp relative to the electronic device.

10. The stand of claim 1 wherein the support is bendable into different positions.

11. The stand of claim 1 wherein the clamp includes a “U”-shaped body operable to hold the probe.

12. The stand of claim 1 wherein the clamp includes a strap operable to hold the probe.

13. The stand of claim 1 wherein the clamp includes:
a body having a mounting surface and a cleat, and
a strap having a first end coupled to the body, and a second end having a hole to receive the cleat, wherein the strap is operable to releasably retain the probe.

14. The stand of claim 1, further comprising a ground-lead holder operable to support a ground lead of the probe.

15. A stand for supporting a signal probe, comprising:
a clamp operable to hold the signal probe; and
a support coupled to the clamp and including a telescoping leg operable to adjust a position of the clamp relative to an electronic device that is to be probed.

16. The stand of claim 15 wherein the support includes three telescoping legs.

17. The stand of claim 15 wherein the support includes:
a body; and
three telescoping legs, each pivotally coupled to the body.

18. A stand for supporting a signal probe, comprising:
a clamp operable to hold the signal probe; and
a support coupled to the clamp and including a magnet operable to mount the support.

19. The stand of claim 18 wherein the support includes a foot that includes the magnet.

20. A stand for supporting a signal probe, comprising:
a clamp operable to hold the signal probe; and
a support coupled to the clamp and including a bendable leg operable to adjust a position of the clamp relative to an electronic device that is to be probed.

21. The stand of claim 20 wherein, after the leg is bent, the leg retains its new position.

22. The stand of claim 20 wherein the support includes two bendable legs.

23. A method comprising:
securing a probe to a stand;
mounting the stand to an electronic device having a circuit node; and
positioning the probe such that a tip of the probe contacts the node.

24. The method of claim 23 wherein securing the probe includes inserting the probe into a “U”-shaped clamp.

25. The method of claim 23 wherein securing the probe includes coupling a strap around a body of the probe and securing the strap to a cleat of a clamp.

26. The method of claim 23 wherein mounting the stand includes magnetically coupling the stand to the electronic device.

27. The method of claim 23 wherein mounting the stand includes adhering the stand to the electronic device with an adhesive.

28. The method of claim 23 wherein positioning the probe includes bending the stand.

29. The method of claim 23 wherein positioning the probe includes extending or retracting a leg of the stand.

30. The method of claim 23 further comprising removing the stand from the electronic device.
